(19) United States
(12) Patent Application Publication
(10) Pub. No.: US 2019/0161859 A1
(43) Pub. Date: May 30, 2019

(54) Apparatus for making large-scale atomic layer deposition on powdered materials with plowing action

(71) Applicants: Ying-Bing Jiang, Albuquerque, NM (US); Hongxia Zhang, Albuquerque, NM (US)

(72) Inventors: Ying-Bing Jiang, Albuquerque, NM (US); Hongxia Zhang, Albuquerque, NM (US)

(21) Appl. No.: 15/826,682

(22) Filed: Nov. 30, 2017

(51) Int. Cl. C23C 16/458; C23C 16/44; C23C 16/455; C23C 16/52

(52) U.S. Cl. CPC C23C 16/4585; C23C 16/4417; C23C 16/52; C23C 16/45561; C23C 16/45544

(57) ABSTRACT

Apparatus for making atomic layer deposition on powdered materials is provided. Inside a vacuum deposition chamber, a stationary but tilted pan-shaped vessel, or non-stationary pan-shaped vessel that is doing tilting movement continuously or intermittently, is used to accommodate powdered samples. A plowing device with teeth or blades is positioned above the pan-shaped vessel, configured to make rotary or sliding movement so as to make plowing actions to the powdered samples, thereby agitate the powdered samples on the pan-shaped vessel. A flattening structure is positioned above the pan-shaped vessel, configured to make rotary or sliding movement, thereby even out the distribution of the powdered samples. The apparatus may comprise multiple pan-shaped vessels or multiple vacuum chambers.

### FIELD OF THE INVENTION

The present invention relates generally to making coatings or surface modifications on powdered materials (including small fibers). More particularly, the present invention relates to an improved apparatus and method for making coatings or surface modifications on powdered materials via a deposition process using sequential precursor exposures, for example, the so-called atomic layer deposition (ALD) process.

### BACKGROUND OF THE INVENTION

Atomic Layer deposition (ALD) process is a layer-by-layer deposition process comprising alternative exposure and purge steps, where the precursors react with the sample surface in a sequentially one-at-a-time manner. A typical ALD process may include the following steps: 1) place a sample in a sealed chamber, evacuate the chamber with a vacuum pump, and keep the sample at certain temperature; 2) introduce the first precursor, say, precursor A, into the chamber. Precursor A may or may not be carried by an inert gas that is called “carrier gas”. In this step, precursor A will chemically react with the sample surface, forming a chemisorbed layer of molecules of precursor A on the sample surface. This step is usually called as “precursor-exposure” step; 3) pump or purge the chamber so as to remove un-reacted precursor A and reaction byproducts, leaving the chemisorbed layer of molecules of precursor A on the sample surface. This step is usually called as “purge” step; 4) introduce the second precursor, say, precursor B, into the chamber, and precursor B will chemically react with the sample surface, converting the chemisorbed layer of molecule A into a solid deposition. Again, this step is called as “precursor-exposure” step; 5) pump or purge the chamber so as to remove un-reacted precursor B and byproducts, providing a fresh surface for another layer of chemisorptions of precursor A. Again, this step is called “purge” step, 6) repeating step 2 to 5 to achieve a number of layers as needed, so as to obtain the thickness of the coating as needed. Detailed ALD process may vary, but they all comprise alternating “precursor-exposure” step and “purge” step, and materials are deposited on a surface in a layer-by-layer manner.

Using an ALD process, the physical or/and chemical properties of a sample surface can be modified, and coatings can build up in a one-atomic-layer by one-atomic-layer fashion, with thickness control in atomic-level precision. In addition, the coatings or modifications are usually uniform and conformal throughout the whole sample surface because the surface reaction and surface adsorption are usually uniform and conformal.

Typically, an ALD apparatus comprises a deposition chamber with at least one pumping port so as to remove gas from the chamber, and at least one gas-injection port so as to bring gas into the chamber.

In general, a successful ALD process requires a good precursor-exposure step and a purge step, which means that precursor molecules should be able to freely reach the sample surface; and after the reaction of precursors at the sample surface, the reaction byproduct and un-reacted residual precursors should be able to be removed easily from the sample surface vicinity. In addition, during the steps of precursor introduction and gas removal, the sample should stay inside of the deposition chamber instead of being blown away by the gas flow.

For a wafer sample, the above requirements can be easily satisfied because the surface geometry of a wafer is simply flat. Transport of gas molecules to and away from this flat surface is easy. In addition, the wafer samples are usually heavy enough so that the samples won't be blown away by the gas flow.

However, when running ALD on small particles, or powdered materials, there are at least three issues: 1) for a plurality of powders, the powders buried at the bottom have less chance to be exposed to the reactant gases, causing problem for “precursor-exposure” step; 2) the gas molecules trapped in between of powders at the bottom have a less chance to be pumped or purged away, causing problem for “purge” step, resulting in non-ALD deposition in these locations; 3) the powders are light and can be easily blown away by the gas flow during the steps of introducing precursors for “precursor-exposure” and the step of pumping for “purge”, making powders being carried by gas flow thereby sticking on the chamber walls, or entering the “pumping port” as mentioned in previous paragraph.

Despite of the above issues, there is an increasing interest in doing ALD on powdered samples (including small fibers) as ALD can be used to modify the surface property of the powdered samples, or to make a thin layer of catalytic or other functional materials on the powder surface. For example, ALD of platinum on porous carbon powders is of great interest in fuel cells applications; ALD of oxide on porous powders can be used for battery electrodes, or super capacitors; ALD of photocatalytic TiO₂ on porous powders can be used for water or air detoxification; ALD of catalysts on ceramics powders can be used to remove NO, CO etc from auto exhaust or the flue gas from electrical plants etc.

To facilitate ALD on powder samples, some researchers have developed a fluidized-bed ALD system, where the powders are blown up and dispersed by turbulent gas flow so that all the powders can have good chances to be exposed to the reactant gases. But there are several disadvantages in this approach: 1) the ALD chamber has to be relatively large to satisfy the configuration of a “fluidized bed”, e.g. several feet in height, especially when less reactive precursors are used and longer residence time is needed to complete the reaction; 2) fluidized bed also requires relatively high gas pressure and large gas flow so that the particles can be blown up by the gas flow, which causes a big waste of carrier gases; 3) powders will fly around vigorously inside the chamber, and a porous filter with small pores has to be used to prevent powders from being pumped away, but this porous filter will trap powders so that many powders are wasted by being trapped inside the pores. Further, once the powders are trapped inside the pores, the filter will be blocked. As a consequence, the filter has to be cleaned or replaced frequently; 4) since powders will fly around inside the chamber, many powders will stick on the chamber walls or be trapped in the porous filters, which are hard to collect after ALD, causing waste of powders and contamination for the following ALD process. Therefore, for this fluidized-bed ALD system, it is hard to process a very small amount of powder due to loss of powders in the filter and the chamber walls. It doesn't work very well if research-scale small amount of powdered samples are processed. [Ferguson et al, Powder Technol., No. 156, page 154, 2005]

In another known art, an ALD system with rotary cylinder is used for powder ALD [McCormick et al, J. of Vac. Sci. and Technol. A, January/February 2007, p 67]. In this art, the ALD chamber is a rotary cylinder, which rotates along a horizontal axis to agitate the powders so as to help achieving good results in “precursor-exposure” step and the “purge” step. In this known art, there are two distinctive features: 1) the cylinder rotates along a horizontal axis; 2) a porous filter has to be used to prevent powders from being blown away. Again, the porous filter will trap powders and may be blocked by the powders after long-term usage.

In a third known art, a flat container is used as a “powder-ALD accessary” in a regular ALD system to hold powered samples, wherein a thin layer of powdered samples are spread over the flat surface. In this case, the pan is stationary, and the powders are stationary. The layer of powders has to be very thin to ensure powders at the bottom to be fully exposed to ALD conditions. As a result, the amount of powders that can be processed by this “powder-ALD accessary” is very limited. In addition, a mesh or porous cap has to be used on the top of the flat container to prevent powders from being blown away by the gas flow.

For large-scale ALD of powdered samples, none of the above know arts seems to be efficient. Therefore, there is a need of developing improved ALD systems to process powdered samples.

### SUMMARY OF THE INVENTION

Briefly, in this invention, we disclose an apparatus for coatings or modifying surfaces of powdered materials comprising:
a. an air-tight vacuum deposition chamber;
b. a broad and shallow container, say, a pan-shaped-vessel inside the vacuum deposition chamber that is configured to accommodate powdered materials, wherein the interior bottom surface of the pan-shaped-vessel may or may not be exactly smooth and flat
   Further, the pan-shaped vessel is either stationary but positioned non-horizontally; or non-stationary and configured to be able to make tilting movement continuously or intermittently during ALD process. To facilitate tilting movement, a tilting axis may be connected directly to the pan-shaped vessel, or connected indirectly to the pan-shaped vessel. e.g. through the vacuum chamber or any supporting platform;
c. a plowing device inside the vacuum deposition chamber and positioned above the pan, wherein: 1) the plowing device comprises at least a beam and many teeth or blades at the bottom side of the beam; and 2) the plowing device comprises a rotation axis that is configured to facilitate a rotary movement of the plowing device, wherein the rotary movement is parallel to the interior bottom surface of pan; or, the plowing device comprises a sliding axis that is configured to facilitate a linear movement of the plowing device, the linear movement is parallel to the bottom surface of the pan-shaped vessel; and 3) the distance between the interior bottom surface of the pan-shaped vessel and the bottom edge of the teeth or blades is within the range of 0-5 mm, or 0-10 mm, or being configured to be adjustable to be within the range of 0-5 mm, or 0-10 mm. But if the powders sample has a large particle size, e.g. larger than 0.1 mm, this number can be well above 10 mm,
   The bottom edge of the beam of the plowing device may or may not be used to flatten and even out the pile of the powdered samples, In case that it is used to flatten the pile of powdered samples, the distance between the bottom edge of the beam and the interior bottom of the pan-shaped-vessel can be within the range of 5-20 mm. But if the powders sample has a large particle size, this number can be well above 20 mm;
d. a flattening structure within the vacuum deposition chamber and above the pan, wherein: 1) the flattening structure comprises at least a beam (e.g., call it “flattening-beam” to differentiate it from the beam in the plowing device), the flattening-beam may or may not have many teeth or other serrated features at the bottom side of the beam; 2) the bottom edge of the flattening-beam is configured to flatten the pile of the powdered samples and even out the distribution of the powdered samples; and 3) the flattening structure comprises a rotation axis that is configured to facilitate a rotary movement of the flattening structure, wherein the rotary movement is parallel to the interior bottom surface of pan; or, the flattening structure comprises a sliding axis that is configured to facilitate a linear movement of the flattening structure, the linear movement is parallel to the bottom surface of the pan-shaped vessel.
   The flattening-beam “flattens” the pile of the powdered samples if the pile of the powdered samples is thick in some location and thin in other locations. The purpose of the teeth or other serrated features at the bottom of the flattening-beam is to dig trenches out of the flattened surface, therefore the pile of the powdered sample has a serrated surface, which is advantageous for efficient exposure/purge steps in ALD process.
   The plowing device and the flattening structure can be two separated parts; or if the beam in the plowing device is not positioned too high above the pile of the powdered samples, the beam will be able to flatten the too high part of the powdered samples, thereby evening out the distribution of the powdered samples. In this case, the plowing device has the function of flattening structure. In another word, the flattening structure is integrated into the plowing device, resulting in a plowing device with flattening structure.
   In general, the bottom edge of the flattening-beam can be positioned to be about 5-20 mm above the interior bottom surface of the pan-shaped vessel. But if the powders sample has a large particle size, this number can be well above 20 mm.
   There may be more than one beams for the plowing device, and more than one flattening-beams for the flattening structure. For all those beams or flattening beams, they may be round, square, rectangle, or hexagonal, or in other shapes, as long as they can rotate or slide above the pan-shaped vessel. The beams may not necessary to be exactly in a long rod shape. For example but not limited b this example, the beams may be transformed from a long rod shape into a perforated flat-plate shape, with teeth or blades accommodated at the bottom of this plate.
e. a gas and precursor delivery unit comprising: 1) at least one source for a vapor-phase or gas-phase reactant; and 2) at least one pneumatic or solenoid valve in between of the vacuum deposition chamber and the source; and 3) at least one device that is configured to regulate the gas flow rate for the gas to be introduced into the vacuum deposition chamber,
f. a vacuum pumping unit comprising: 1) at least one vacuum pump; and 2) at least one valve in between of the vacuum deposition chamber and the vacuum pump;
g. a controller unit comprising: 1) at least one sub-unit configured to control the actions of the automatic valves; and 2) at least one sub-unit configured to control the temperature of the powdered materials; and 3) at least one sub-unit configured to control the mechanical movement of the plowing device.

Further, the apparatus may comprise more than one vacuum chambers, or more than one pan-shaped vessels. And more than one vacuum chamber or pan-shaped vessels may be stacked or arrayed together and may also tilt together.

### BRIEF DESCRIPTION OF THE DRAWINGS

In the following, a more particular description of the invention may be had by reference to embodiments, some of which are illustrated in the appended drawings.

FIG. 1 is a schematic illustration of an exemplary ALD apparatus with a tilting pan-shaped vessel and a plowing-device with flattening structure;

FIG. 2 is a zoom-in schematic of an exemplary tilting pan-shaped vessel and a plowing-device with flattening structure, with another mounting option of the tilting axis;

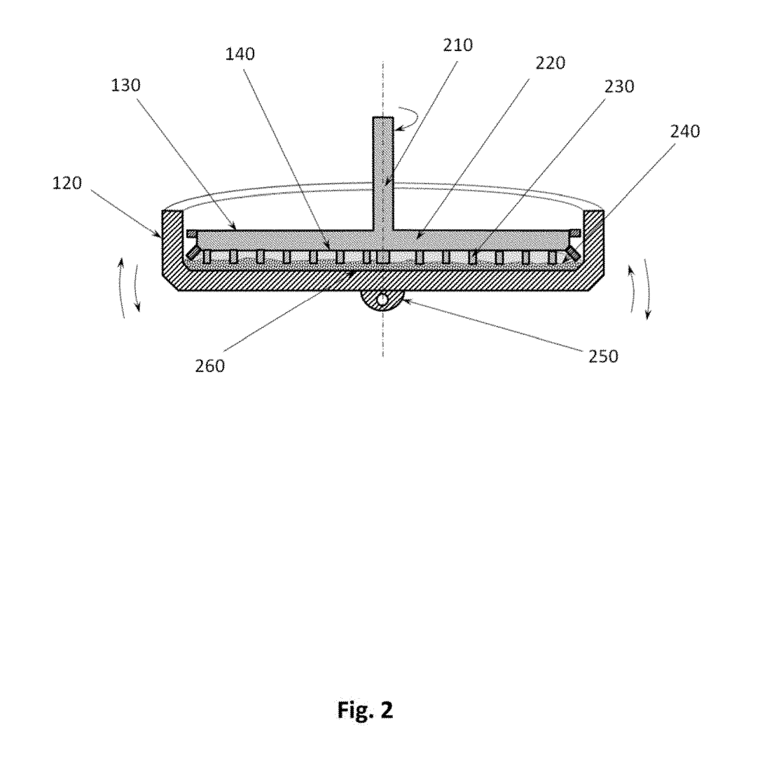

FIG. 3 is a more detailed illustration of the structure of an exemplary plowing-device with flattening structure, including the arrangement of the teeth or blades and alternative shape of the serrated feature for the flattening structure;

FIG. 4 is a schematic illustration showing a pile of non-uniform powdered samples before and after being evened out by the flattening structure;

FIG. 5 is an electron microscope image of an exemplary powdered sample coated by such an ALD apparatus.

### DETAILED DESCRIPTION OF THE EMBODIMENTS

In this invention, we provide an improved apparatus for making coatings or surface modifications on powdered materials (including small fibers) via a layer-by-layer deposition process using alternating “precursor-exposure” and “purge” steps, such as the so-called atomic layer deposition process.

In one embodiment of this invention, the ALD system comprises a tilting or tilted pan-shaped vessel, and the tilting or tilted pan-shaped-vessel is used as the container for the powdered samples. As mentioned in previous paragraph, such a flat container (say, the pan-shaped vessel) has been used as a “powder-ALD accessary” in a regular ALD system in previous know art, but different from the previous known art, wherein the pan was typically positioned horizontally and stationary, the tilting or tilted “pan-shaped vessel” in this invention is either stationary but positioned non-horizontally, or keeps doing a tilting movement (or, in another word, keeps moving toward a non-horizontal position) during ALD process, making the powdered samples on the pan to be sliding around during ALD process. For example but not limited to this example, the tilting movement of the “tilting pan-shaped vessel” can be a simple back-and-forth tilting motion along a horizontal axis, wherein the horizontal tilting axis is a stationary axis, or, the tilting movement is a more complex tilting motion wherein the tilting axis is also moving when the “pan-shaped vessel” is tilting (for example but not limited to this example, the tilting axis itself is also rotating along a vertical axis), therefore the overall movement of the “tilting pan-shaped vessel” is a tilting motion with the tilting direction changes from time to time.

To facilitate the tilting movement as mentioned above, the pan has an axis for tilting, or, the pan is supported by a mechanism with an axis for tilting, wherein the tilting axis can be either horizontal, or non-horizontal, either stationary, or nonstationary. To control the tilting movement, an automation unit is used in this ALD system to make the tilting movement controllable. To enhance the agitation of the powder caused by the tilting motion of the pan, the surface of the pan may or may not comprise extruding objectives such as rods, blades.

In a second embodiment of this invention, the ALD apparatus not only comprises a “pan-shaped vessel” (either tilting, or stationary but in a tilted position, or stationary and in a horizontal position) to hold the powdered samples, but also comprises a “plowing device” that is positioned above the pan. For example but not limited to this example, the “plowing device” may have a comb-shaped or rake-shaped structure comprising a beam with many teeth or blades, so that the powdered samples will be plowed or stirred or agitated by the teeth or blades when the “plowing device” is moving. The plowing movement of the “plowing device” may be a linear movement, or a rotary movement along a horizontal axis, or a rotary movement along a vertical axis, or a movement of the combination of many kinds of movements. To ensure efficient stirring action or agitation of the powdered sample, during the plowing movement, the gap between the teeth or blade of the “plowing device” and the bottom of the “pan-shaped vessel” should be as close as possible, for example, within the range of 0-5 mm, or, 0-10 mm, or 0-20 mm if the particle size of the powdered samples is large.

In a third embodiment of this invention, besides the “plowing device”, there is also a “flattening structure” on top of the pan. After being agitated by the “plowing device”, especially when the pan-shaped-vessel 120 is tilted or keeps doing tilting movement during ALD process, the pile of the powdered samples in the pan-shaped-vessel may be thick and thin from location to location. The purpose of the “flattening structure” is to even out or “flatten” the powder surface, making the thickness of the pile of the powdered samples to be relatively uniform. The surface of the piled powdered sample, however, does not have to be exactly flat and smooth. On the contrary, the surface can be a serrated or waved surface but the “average thicknesses” (if the surface is serrated) are relatively uniform from location to location. This is why in the flattening structure, we not only need a bottom edge to flatten the powdered samples, but also need some teeth or other serrated features to generate trenches in the pile of the powdered samples, making more powdered sample to be exposed to the surface for better exposure/purge steps for ALD. The “plowing device” and the “flattening structure” may be two separated device, or, they may be integrated into one single device, e.g. a plowing device with flattening structure.

As a further improvement, the assembly of the “pan-shaped vessel” and the “plowing device” on its top may tilt as a whole unit. In another word, the “pan-shaped vessel” and the “plowing device” are mounted together to form an assembly. This assembly keeps doing a tilting movement (or, in another word, keeps moving to a non-horizontal position) during ALD process, making the powdered samples on the pan not only to be sliding around during ALD process, but also being agitated by the “plowing device” as well as being flattened by the “flattening structure” for uniform thickness after agitation. For example but not limited to this example, the tilting movement of the “tilting pan-shaped vessel” can be a simple back-and-forth tilting motion along a horizontal axis, wherein the horizontal tilting axis is a stationary axis, or, the tilting movement is a more complex tilting motion wherein the tilting axis is also moving when the “pan-shaped vessel” is tilting (for example but not limited to this example, the tilting axis itself is also rotating along a vertical axis), therefore the overall movement of the “tilting pan-shaped vessel” is a tilting motion with the tilting direction changes from time to time.

In a forth embodiment of this invention, the ALD system comprises more than one assembly of the “pan-shaped vessel” and the “rotary stirring device”. Those assemblies are stacked together, or arrayed together, so that in one batch of ALD process, more powdered samples can be processed.

### EXAMPLES

The present invention will now be explained, in detail, by reference to but without limitation by the following Examples.

### Example 1, ALD System with Tilting Pan and Plowing Device with Flattening Structure

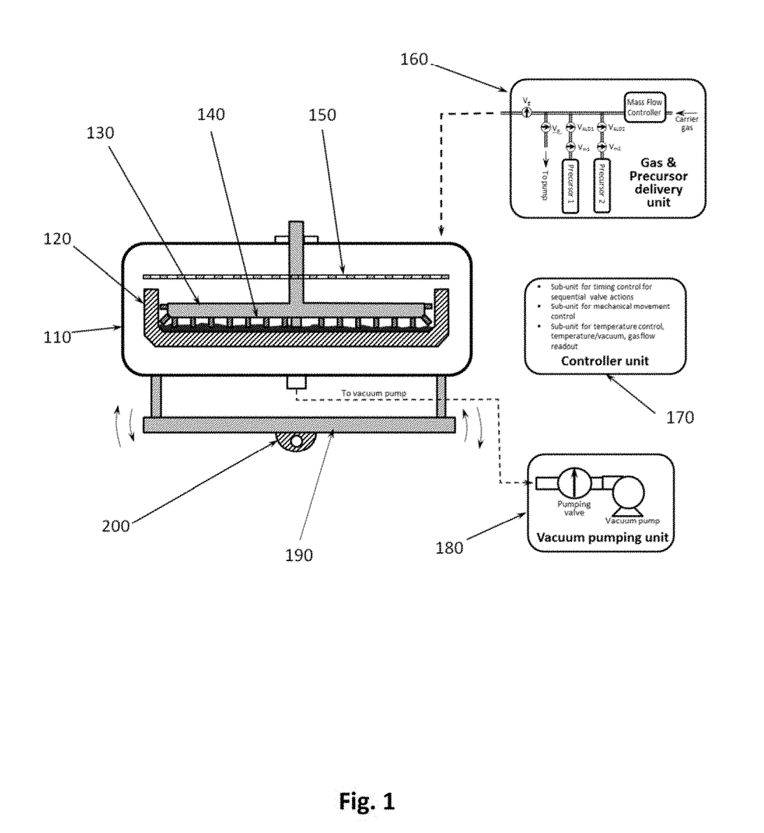

FIG. 1 is a schematic of the structure of an exemplary ALD apparatus system. The system comprises at least a vacuum pumping unit 180, a controller unit 170, a precursor delivery unit 160, and a vacuum deposition chamber 110.

The vacuum pumping unit 180 is used to pump gases away from the vacuum deposition chamber. It may comprise one or more vacuum pumps, one or more vacuum hoses/pipes/tubings, one or more vacuum valves etc. The pumps and the valves may or may not be automatically controlled by the controller unit 170.

The gas delivery unit 160 is used to provide precursor gases or vapors for atomic layer deposition that happens in the deposition chamber 110. It may comprise one or more precursor bottles, one or more pneumatic vacuum valves, one or more manual vacuum valves, one or more vacuum tubings or manifolds, one or more mass flow controllers, may or may not comprise precursor heaters etc. In this specific example, there are two precursor bottles. For each precursor bottle, there is a manual shut-off valve. In between of the vacuum deposition chamber and the precursor bottle, there is an ALD valve, which is typically a pneumatic automatic valve. The actions of the ALD valves are controlled by the controller unit 170. In this particular example, there is a main gas line that brings gas and precursor vapors (gases) into the vacuum deposition chamber 110. Before the gas enters into the vacuum deposition chamber 110, there is a Vg valve, and a bypass valve Vp that brings gases to the pumping unit 180 if needed. In the main gas line, there is a mass flow controller to control the gas flow of the carrier gas. In this example, the two precursor lines share the same mass flow controller. In other examples, each precursor bottle may have a carrier gas and a mass flow controller.

The controller unit 170 may comprise the following sub-units: 1) the sequential valve action timing control sub-unit; 2) the mechanical movement control or driving sub-unit; 3) the temperature control sub-unit. The controller unit 170 is used to control the status of the open/close actions of the valves, the timing sequence of the open/close actions of the valves, therefore the controller unit in this example comprises at least a timing control device; The controller unit 170 may also have the capability of reading/controlling the temperatures of a number of heaters, including the heater(s) for the deposition chamber, the powdered sample, the precursor bottles, the gas delivery tubing(s)/hose(s) etc; The controller unit 170 may further has the capability of controlling the tilting movement of the pan-shaped-vessel 120 or the tilting movement of the whole deposition chamber 110, as well as the movement of the plowing device 130 and the flattening structure 140.

Within the deposition chamber 110, there is a flat “pan-shaped vessel” 120 that is used to hold the powdered samples. This pan-shaped-vessel 120 may or may not be connected to a tilting axis 200 or 250 that enables the pan 120 to make tilting movement. When the pan 120 tilts, powdered samples will be sliding around, giving a better opportunity to bring the powdered sample buried at the bottom to the surface for uniform exposure/purge of ALD process. The tilting axis 200 or 250 may be connected directly to the pan directly, or connected to the pan indirectly. For example, the axis 200 can be connected to a supporting frame 190 that is supporting the vacuum deposition chamber 110 thereby also supporting the pan-shaped-vessel 120. In another word, the tilting axis 200 can be connected to the deposition chamber 110 or a supporting structure that supports the chamber 110. Since pan 120 can be supported by the deposition chamber 110, it will tilt together with the deposition chamber 110. Further, there can be more than one tilting axis connected to the pan 120 directly or indirectly, enabling the pan to tilt to various directions for more efficient agitation of the powdered samples.

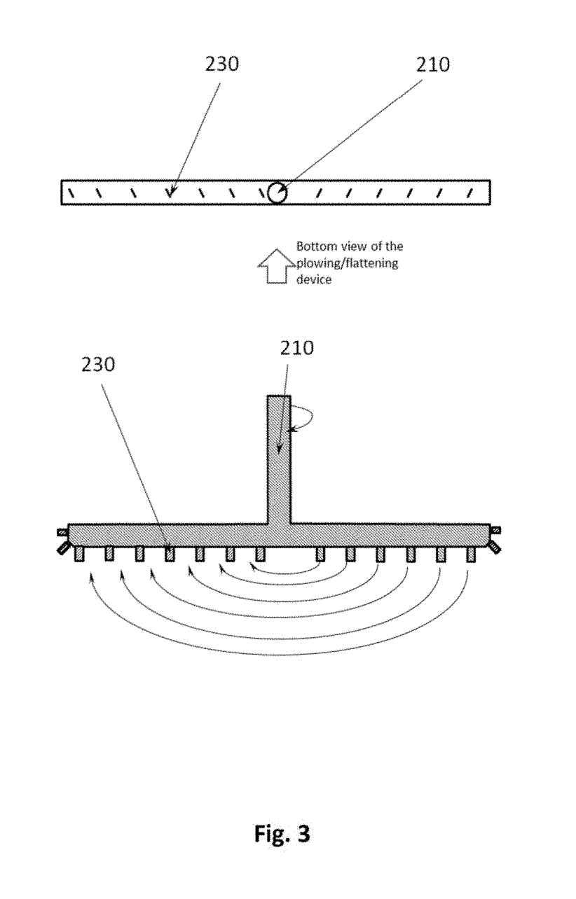

Above the pan-shaped-vessel 120, there is a plowing device 130. In this specific example, the plowing device comprises a beam 220 and many teeth (or blades) 230 at the bottom of the beam 220. The plowing device 130 further comprises a rotary axis 210 that enables the plowing device 130 to rotate above the pan-shaped-vessel 120, plowing the powdered samples 240 thereby brings powdered samples at the bottom to the surface. In this specific example, the beam 220 of the plowing device 130 is shaped as a long rod. There are 7 blades 230 at the bottom of the left arm of the beam 220, and 6 blades 230 at the bottom of the right arm of the beam 220. The blade-to-axis distances in the left arm of the beam 220 are different from the blade-to-axis distances in the right arm, therefore the powdered samples 240 that are not plowed by the blades 230 in left arm (because they are in between of two blades) will be plowed by the blades in the right arm, enabling a more thorough plowing action. (refer to FIG. 3) On the two side edges of the beam 220, there are also two blades 230. Those two blades on the sides can be made of soft and flexible material. They function like two brushes. When the powdered samples are plowed by the plowing device 130, and when the pan-shaped-vessel 120 tilts, some powdered samples 240 may go to the side of the pan 120. Those two blades will brush off the powdered samples on the side edge of the pan-shaped-vessel 120, preventing powdered samples from getting out of the pan 120.

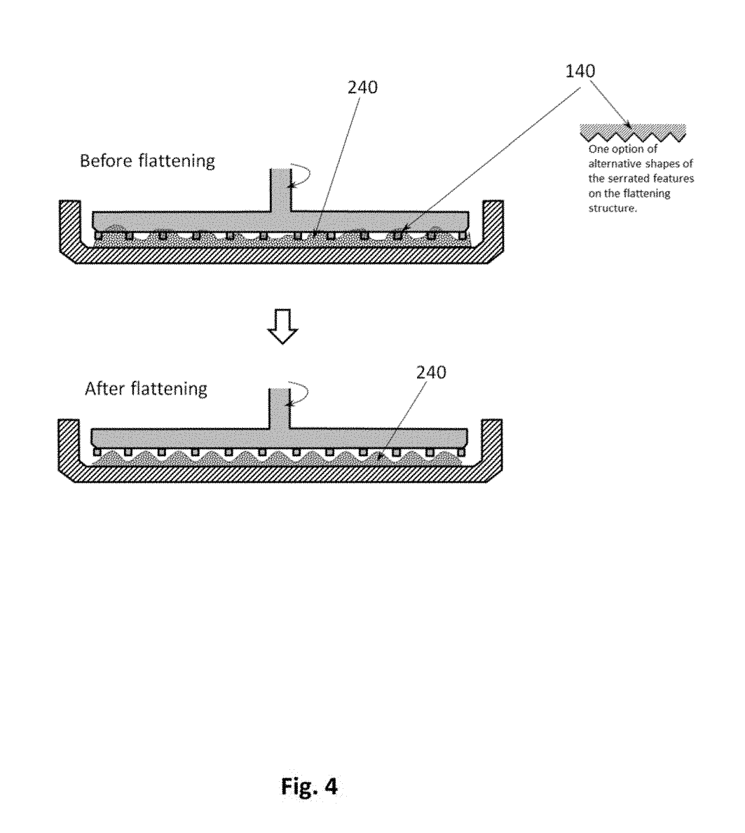

After many times of plowing actions, especially when the pan-shaped-vessel 120 is tilted or keeps doing tilting movement during ALD process, it is possible that some powdered samples 240 may gradually be pushed to some locations and get accumulated in those locations, and in other locations the powdered samples become less and less. Therefore, the powdered samples may become very thick in some locations and be depleted in other locations, causing non-uniform exposure/purge for ALD. To prevent the pile of the powdered sample 240 from being too thick in some locations while depleted in other locations, a flattening structure 140 is used to flatten the surface of the pile of the powdered sample. A flattening structure 140 is a structure that can push the excessive powdered samples away from the too thick locations. Structurally, it may comprise rotating or sliding beam, herein named as “flattening beam” 410, with serrated features 420 such as teeth or blades as shown in FIG. 4. The bottom edge of the flattening-beam 410 is positioned above the pile of the powdered samples with a proper pan-to-edge distance, which is the distance between the interior bottom surface of the pan-shaped-vessel 120 and the bottom edge of the flattening-beam 410, so that it can flatten out the peak(s) of the pile of the powdered samples, thereby makes the powdered samples evenly distributed on the pan-shaped-vessel. Again, although overall the bottom edge of the flattening structure can be relatively straight in general (but it can also be cured if the interior bottom of the pan 410 is a spherical surface), it may have detailed structures. For the sample, the edge may comprise zigzag or serrated features 420 such as teeth or blades as shown in FIG. 4, just like the edge of a saw, wherein the teeth of the saw can be triangular, or square, or in other shapes.

The flattening structure 140 and the plowing device 130 may be two separated devices, or, may be combined into one single device. In this specific example, the plowing device is bot only configured to be able to plow, but also configured to be able to flatten the powdered samples. Therefore, the flattening device and the plowing device are combined into one single device, say, a plowing device with flattening structure. Therefore in this specific example, the flattening structure 140 and the plowing device 130 as shown in FIG. 1 actually refer to the same part in the ALD apparatus.

For the plowing device 130, its major function is to stir or agitate the powdered samples and bring the powdered samples from the bottom to the surface. To efficiently fulfill this function, structurally, the gap between its teeth or blades 230 and the interior bottom surface of pan 120 should be as small as possible, for example, 0-5 mm, or 0-10 mm. But if the powdered samples have a large particle size, e.g. larger than 0.1 mm, this number can be well above 10 mm. Further, the front surfaces of the teeth or blades 230 of the plowing device may be tilted forward along its moving direction so that the powdered samples can be plowed out and flipped up from the bottom to the surface. Besides tilting forward, the surface of the teeth or blades may also be twisted to the side (refer to FIG. 3), so that the powdered samples can be pushed to one side in a controlled manner instead of randomly building up upward then falling apart.

For the flattening structure 140, its major function is to even out the distribution of the powdered samples 240. To efficiently fulfill this function, structurally, the distance between the bottom edge of the flattening beam 410 and the interior bottom surface of pan 120 cannot be too large, nor be too small. Ideally, this distance is about the same as the thickness when the powdered samples are uniformly spread over the pan 120. Therefore, ideally, the height of the flattening structure 140 is adjustable according to the amount and the nature of the powdered samples to be treated. If it is not adjustable, the distance can be less than 20 mm, or less than 15 mm, or less than 10 mm, or less than 5 mm. If the particle size of the powdered samples is very large, e.g. larger than 0.1 mm, this distance can actually be well above 20 mm.

To prevent powdered samples from flying around thereby causing too much contamination to the deposition chamber, there may or may not be a mesh 150 on top of the plowing device 130 and the flattening structure 140. This mesh 150 not only reduces the chamber contamination by the powdered samples, but also makes the pumping (or gas evacuation) and precursor gas injection steps to be more uniform and more gentle.

The plowing action helps agitate the powdered samples. To further enhance the agitation of the powdered samples, the pan-shaped-vessel may be stationary but positioned non-horizontally, or, the pan-shaped-vessel may keep making tilting movements continuously or intermittently during ALD process. To facilitate this tiling movement, the vacuum deposition chamber can be mounted on a supporting platform 190 with a tilting axis 200 as shown in FIG. 1.

In this specific example, ALD on powdered samples can proceed through the following procedures:
1) Vent and open the deposition chamber, load powdered sample on to the pan 120;
2) Close and pump the chamber. When the pressure in the deposition chamber is lower than 1 Torr, the controller unit will generate a signal, providing a driving powder to make the plowing device and the flattening device to rotate, therefore the pumping process for the powdered samples is more efficient;
3) Before, or during, or after the rotatory movement of the plowing device and the flattening device, the pan is tilting back and forth. The tilting movement is controlled by the controller unit.
4) Before or during the pumping process, the controller unit generate signal to heat the powdered samples;
5) When pumping starts, or at certain point after pumping starts, some inert gas such as N2 or Ar, may or may not be introduced into the deposition chamber, purging the deposition chamber. The mass flow of the gas is controlled by the controller unit;
6) When the sample temperature is stabilized and the powdered samples are fully pumped, the vapor of a first precursor is introduced into the deposition chamber, e.g. by opening the V_{ALD1} valve as shown in FIG. 1, which is controlled and timed by the controller unit. The first precursor reacts with the powdered samples, forming a first chemisorption on the powder surfaces;
7) The deposition chamber is pumped and purged by inert gas, removing reaction byproducts in step “5)” and excessive precursor vapor.
8) The vapor of a second precursor is introduced into the deposition chamber, reacting with the powdered samples, converting the first chemisorption into a layer of solid deposition on the powder surfaces
9) The deposition chamber is pumped and purged by inert gas, removing reaction byproducts in step “7)” and excessive precursor vapor.
10) Repeating steps “5)” to “8)” for certain times to achieve needed thickness of the deposition.

In this specific example there are two precursors involved in the ALD process. But in other cases there can be more than two precursors involved in the ALD process. The “vapor of a precursor” can simply be a reactive gas instead of “vapor”, or a vapor-phase reactant, or a plasma, or reactive radicals generated in or introduced into the vacuum chamber, or an energy source that is capable to drive the deposition reaction such as UV irradiation etc.

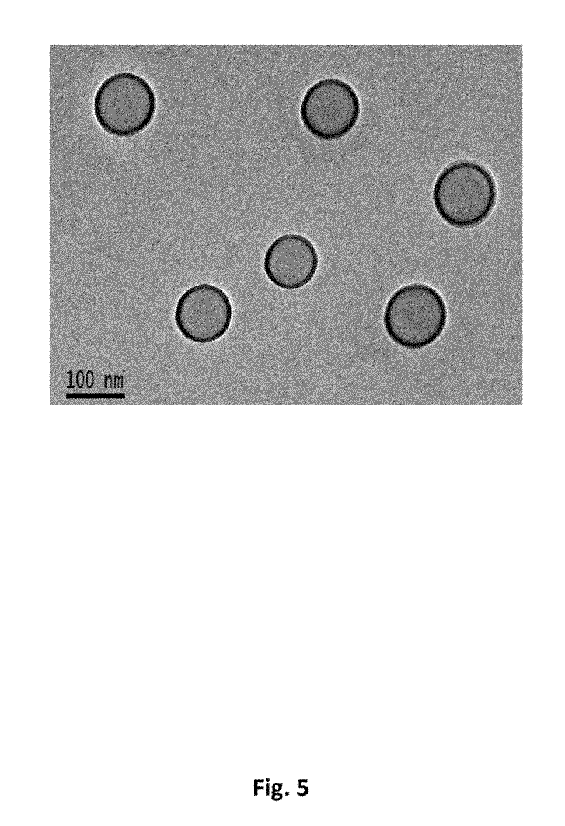

FIG. 5 is an electron microscope image of a powdered sample treated in this apparatus. It is evident that the depositions on the particles are thin, uniform and conformal.

### Example 2, ALD System with Stationary but Tilled Pan

For research and development purpose, a simplified version of the ALD apparatus may comprise a stationary pan-shaped-vessel 120 wherein the pan 120 is not making tilting movement during ALD process. In this ALD apparatus, the pan-shaped-vessel 120 is stationary, but the interior bottom surface of the pan-shaped vessel 120 is in a non-horizontal position. The angle between the interior bottom surface and the horizontal direction may be within 5-45 degree, or 5-30 degree. The ALD apparatus further comprises a rotary plowing device 130, may or may not further comprise a flattening structure 140.

### Example 3, Multi-Pan ALD System with Plowing Device

For large scale ALD process, powdered samples are easy to be loaded to or collected from the pan-shaped-vessel. The large opening of the “pan” makes it easy to clean and easy to do maintenance, therefor an ALD system using pan-shaped-vessel to hold samples is advantageous in certain aspects. To improve the yield for each run, multiple pan-shaped-vessels may be stacked or arrayed together. They may be positioned in their own vacuum depositions chambers, or share one big vacuum deposition chamber.

### Example 4, Multi-Chamber ALD System with Pan-Shaped-Vessel Traveling Between Chambers

In another example it comprises at least two vacuum chambers. There is an air-tight door between the two chambers. The “pan” can be transferred from one chamber to another chamber. For one of the chambers, the main purpose is to do precursor exposure step of ALD, for the other chamber, the main purpose is to do purge step of ALD. There can be a transition chamber in between of the two chambers. Because each vacuum chamber is dedicated to one step of ALD process, the pumping or precursor exposure steps will be much faster and more efficient than the case when all ALD steps (including precursor exposure, reaction holding, and purging steps etc.) are done in one vacuum chamber. Briefly, in this ALD system, it comprises: 1) using pan-shaped vessel to accommodate powdered samples; 2) the pan-shaped vessel is configured to be able to travel between chambers, thereby bringing powdered samples from one chamber to another chamber; 3) the pan-shaped vessel may be tilted or making tiling movement during ALD process; 4) the system may or may not further comprise a plowing device or flattening structure.

Although the forgoing invention has been described in terms of certain preferred embodiments, other embodiments will become apparent to those of ordinary skill in the art in view of the disclosure herein. Accordingly, it is noted that the above specifications and examples be considered as exemplary only, not a limiting of the scope.

What is claimed includes:

1. An apparatus for coatings or modifying surfaces of powdered materials comprising:
a. a vacuum deposition chamber that is air-tight; and
b. a pan-shaped vessel inside the vacuum deposition chamber that is configured to accommodate powdered materials, wherein the interior bottom surface of the pan-shaped-vessel may or may not be exactly flat and smooth; and
c. a plowing device inside the vacuum deposition chamber and positioned above the pan-shaped-vessel, wherein: 1) the plowing device comprises at least a beam and many teeth or blades at the bottom side of the beam; and 2) the plowing device comprises a rotation axis that is configured to facilitate a rotary movement of the plowing device, the rotary movement is parallel to the interior bottom surface of pan-shaped vessel; or, the plowing device comprises a sliding axis that is configured to facilitate a linear movement of the plowing device, the linear movement is parallel to the interior bottom surface of the pan-shaped vessel; and 3) the gap between the interior bottom surface of the pan-shaped vessel and the teeth or the blades of plowing device is within the range of 0-10 mm, or configured to be adjustable to be in the range of 0-10 mm; and
d. a gas and precursor delivery unit comprising: 1) at least one source for a vapor-phase or gas-phase reactant; and 2) at least one automatic valve in between of the vacuum deposition chamber and the source; and 3) at least one gas flow controlling device that is configured to regulate the gas flow rate for the gas to be introduced into the vacuum deposition chamber; and
e. a vacuum pumping unit comprising: 1) at least one pump; and 2) at least one valve in between of the vacuum deposition chamber and the pump; and
f. a controller unit comprising: 1) at least one sub-unit configured to control the actions of the automatic valves; and 2) at least one sub-unit configured to control the temperature of the powdered materials; and 3) at least one sub-unit configured to control the mechanical movement of the plowing device.

2. The apparatus in claim 1, further comprises a flattening structure within the vacuum deposition chamber and above the pan-shaped vessel, wherein: 1) the flattening structure comprises at least a secondary beam; and 2) the bottom edge of the secondary beam is positioned 5-20 mm above the interior bottom surface of pan-shaped vessel, or configured to be adjustable to be in the range of 5-20 mm above the interior bottom surface of the pan-shaped vessel; and 3) the flattening structure comprises a rotation axis that is configured to facilitate a rotary movement of the flattening structure, wherein the rotary movement is parallel to the interior bottom surface of the pan-shaped vessel; or, the flattening structure comprises a sliding axis that is configured to facilitate a linear movement of the flattening structure, the linear movement is parallel to the interior bottom surface of the pan-shaped vessel

3. The apparatus in claim 2, wherein the flattening structure and the plowing device are made into one piece, the beam for the plowing device and the secondary beam for flattening device are the same beam.

4. The apparatus in claim 1, wherein the pan-shaped vessel is non-horizontally positioned, the angel between the pan-shaped-vessel and the horizontal direction is between of 5-45°, or 5-30°.

5. The apparatus in claim 1, further comprises a tilting axis that is configured to facilitate the tilting movement of the pan-shaped vessel during ALD process.

6. The apparatus in claim 1, wherein the beam is round, or square, or rectangular, or triangular, or hexagonal, or or in other rod-like shapes, or in a vertical plate-like shape, or in a horizontal perforated plate-like shape.

7. The apparatus in claim 1, further comprises multiple vacuum deposition chambers, and the pan-shaped-vessel is configured to be able to travel between vacuum chambers.

8. The apparatus in claim 1, further comprises multiple pan-shaped vessels.

9. The apparatus in claim 2, wherein the pan-shaped vessel is non-horizontally positioned, the angel between the pan-shaped vessel and the horizontal direction is between of 5-45°, or 5-30°.

10. An apparatus for coatings or modifying surfaces of powdered materials using multiple alternating exposure and purge steps, the apparatus comprising:
a. a vacuum deposition chamber that is air-tight; and
b. a pan-shaped-vessel inside the vacuum deposition chamber that is configured to accommodate powdered materials; and
c. a plowing device inside the vacuum deposition chamber and positioned above the pan-shaped-vessel, wherein: 1) the plowing device is a device that comprises at least a beam and many teeth or blades at the bottom side of the beam; and 2) the plowing device comprises a rotation axis that is configured to facilitate a rotary movement of the plowing device, wherein the rotary movement is parallel to the interior bottom surface of pan-shaped-vessel; and 3) the gap between the teeth or blades and the interior bottom surface of the pan-shaped vessel is within the range of 0-5 mm or configured to be adjustable to be in the range of 0-5 mm; and 4) the gap between the bottom edge of the beam and the interior bottom surface of the pan-shaped-vessel is within the range of 5-20 mm or configured to be adjustable to be in the range of 5-20 mm; and
d. a gas and precursor delivery unit comprising: 1) at least one source for a vapor-phase or gas-phase reactant; and 2) at least one pneumatic or solenoid valve in between of the vacuum deposition chamber and the source; and 3) at least one gas flow controlling device that is configured to regulate the gas flow rate for the gas to be introduced into the vacuum deposition chamber; and
e. a vacuum pumping unit comprising: 1) at least one vacuum pump; and 2) at least one valve in between of the vacuum deposition chamber and the vacuum pump; and
f. a controller unit comprising: 1) at least one sub-unit configured to control the actions of the automatic valves; and 2) at least one sub-unit configured to control the temperature of the powdered materials; and 3) at least one sub-unit configured to control the mechanical movement of the plowing device; and
g. An axis that is configured to facilitate continuous or intermittent tilting movement of the pan-shaped vessel.

11. The apparatus in claim 10, wherein the beam is round, or square, or rectangular, or triangular, or hexagonal.

12. The apparatus in claim 10 wherein the interior bottom surface of the pan-shaped vessel is flat.

13. The apparatus in claim 10, wherein the tilting axis is connected directly to the pan-shaped vessel.

14. The apparatus in claim 10, wherein the tilting axis is connected to a frame that is connected to the vacuum deposition chamber or the pan-shaped vessel

15. The apparatus in claim 10, wherein more than one beam for the plowing device are used.

16. The apparatus in claim 10, wherein the apparatus further comprises more than one vacuum chambers, and the pan-shaped vessel is configured to be able to travel in between of the vacuum chambers.

17. The apparatus in claim 10, wherein the apparatus comprises more than one pan-shaped vessels.

18. The apparatus in claim 10, wherein the beam is round, or square, or rectangular, or triangular, or hexagonal, or in other rod-like shapes, or in a vertical plate-like shape, or in a horizontal perforated plate-like shape.
